(19) United States
(12) Patent Application Publication
(10) Pub. No.: US 2007/0230125 A1
(43) Pub. Date: Oct. 4, 2007

(54) Assembly of heat-dissipating device and circuit board

(75) Inventors: Kun-Hang Lo, Hsichih (TW); Ming-Feng Hsieh, Hsichih (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: AOPEN INC., Hsichih (TW)

(21) Appl. No.: 11/647,686

(22) Filed: Dec. 28, 2006

(30) Foreign Application Priority Data
Apr. 3, 2006 (TW) 095205579

(51) Int. Cl. H05K 7/20

(52) U.S. Cl. 361/697

(57) ABSTRACT

In an assembly of a heat-dissipating device and a circuit board, the circuit board has a heat-generating component and is formed with board holes. The heat-dissipating device includes a base plate, a heat-dissipating component, fastening members, biasing members, engaging members, and resilient washers. The base plate abuts against the heat-generating component, and is formed with through-holes. The heat-dissipating component is disposed on the base plate. Each fastening member has a shank part extending through one through-hole and one board hole, a head part, and a threaded connection part. Each biasing member abuts against the base plate and the head part of one fastening member. Each engaging member is disposed at a lower surface of the circuit board and engages the threaded connection part of one fastening member. Each washer is sleeved on one fastening member, and abuts against an upper surface of the circuit board.

### CROSS-REFERENCES TO RELATED APPLICATIONS

This application claims the priority of Taiwanese Application No. 095205579, filed Apr. 3, 2006, the full disclosure of which is incorporated herein by reference.

### BACKGROUND OF THE INVENTION

1. Field of the Invention

The invention relates to an assembly of a heat-dissipating device and a circuit board, more particularly to an assembly including a heat-dissipating device, a circuit board and resilient washers.

2. Description of the Related Art

In general, a heat-dissipating device and a circuit board are assembled using a specially designed fastening member to achieve the effect of secure engagement. However, when using the specially designed fastening member for assembly, mold costs for manufacturing the fastening member are incurred, thereby resulting in higher production costs.

Another manner of assembly uses relatively low cost screw fasteners. As shown in FIG. 1, a heat-dissipating device 1 includes a base plate 11 disposed above a circuit board 2, a plurality of spaced apart heat-dissipating fins 12 mounted uprightly on the base plate 11 and disposed above a central processing unit (CPU) 20, and a fixing device 13. The fixing device 13 includes a plurality of screws 131 extending through two sides of the base plate 11 and the circuit board 2, a plurality of nuts 136, and a plurality of springs 134. A shank part 132 of each screw 131 is sleeved by one of the springs 134, which has opposite ends that abut respectively against the base plate 11 and a head part 133 of the screw 131. During the process of fastening, the screws 131 are rotated and pressed downward such that threaded connection parts 135 at bottom ends thereof extend through the circuit board 2 and engage threadedly the nuts 136 disposed on the bottom surface of the circuit board 2 so that the heat-dissipating device 1 abuts closely against the central processing unit (CPU) 20. However, since friction is generated upon contact between a bottom face of the shank part 132 of each screw 131 and the top surface of the circuit board 2, the surface of the circuit board 2 is damaged, which can result in the likelihood of a short circuit.

In order to solve the above problem, the fastening force between the bottom face of the shank part 132 of each screw 131 and the top surface of the circuit board 2 may be reduced. This, however, results in a problem that the heat-dissipating device 1 is prone to be undesirably removed.

As shown in FIG. 2, another solution is to avoid direct contact between the screws 131 and the circuit board 2. That is, shank parts 138 of the screws 131 can pass movably through holes 21 in the circuit board 2. The outer diameter of the shank part 138 of each screw 131 is smaller than that of the shank parts 132 shown in FIG. 1 so that bottom faces of the shank parts 138 will not press against the top surface of the circuit board 2. However, because of a clearance between the shank part 138 of each screw 131 and the wall of the corresponding hole 21, and a clearance between the top surface of the circuit board 2 and a fastening ring 137 that engages an outer surface of the shank part 138, the heat-dissipating device 1 can hardly be secured stably on the circuit board 2, which likewise results in the heat-dissipating device 1 being prone to be undesirably removed. Moreover, since the screws 131 do not abut directly against the circuit board 2, when the heat-dissipating device 1 is subjected to an external force (A) during impact, the heat-dissipating device 1 is likely to press directly and downwardly the central processing unit 20, thereby resulting in damage to the central processing unit 20 due to the applied force.

### SUMMARY OF THE INVENTION

Therefore, the object of the present invention is to provide an assembly of a heat-dissipating device and a circuit board that has shock-absorbing functionality and that can ensure stable securing.

Accordingly, an assembly of the present invention comprises a circuit board and a heat-dissipating device.

The circuit board has a heat-generating component mounted on an upper surface thereof, and is formed with a plurality of spaced apart board holes.

The heat-dissipating device includes a base plate, a heat-dissipating component, a plurality of fastening members, a plurality of biasing members, a plurality of engaging members, and a plurality of resilient washers.

The base plate is disposed to abut against a top surface of the heat-generating component, and is formed with a plurality of through-holes, each of which is aligned with a respective one of the board holes.

The heat-dissipating component is mounted on top of the base plate, and is disposed above the heat-generating component.

Each of the fastening members includes a shank part extending through one of the through-holes in the base plate and one of the board holes in the circuit board, a head part connected to a top end of the shank part and having an outer diameter larger than that of the shank part, and a threaded connection part extending downwardly from the shank part.

Each of the biasing members has opposite ends that abut respectively against the base plate and a bottom face of the head part of a corresponding one of the fastening members.

Each of the engaging members is disposed at a lower surface of the circuit board and engages the threaded connection part of a respective one of the fastening members.

Each of the resilient washers is sleeved on the shank part of a respective one of the fastening members, and abuts against the upper surface of the circuit board.

Preferably, each of the resilient washers is made of a dielectric rubber material. The shank part of each of the fastening members has an outer surface formed with an engaging groove that is disposed adjacent to the threaded connection part for engaging the respective one of the resilient washers.

Preferably, the heat-dissipating component includes a plurality of spaced apart upright heat-dissipating fins. The heat-dissipating device further includes a heat-dissipating fan mounted on top of the base plate for generating heat-dissipating air flow toward the heat-dissipating component.

Preferably, the base plate includes a first plate body mounted with the heat-dissipating component, a second plate body mounted with the heat-dissipating fan and disposed at a horizontal level lower than that of the first plate body, and a connecting portion interconnecting the first and second plate bodies. At least one of the through-holes is formed in the first plate body adjacent to the connecting portion.

Preferably, the heat-dissipating device further includes a cover body mounted on top of the base plate and disposed to cover the heat-dissipating component and the heat-dissipating fan. The cover body has a top side formed with an air intake hole for establishing fluid communication between the heat-dissipating fan and the outside environment, and a rear side formed with an air vent hole for establishing fluid communication between the heat-dissipating component and the outside environment. The heat-dissipating device further includes a sound-absorbing member mounted on a top side of the first plate body and disposed adjacent to the air vent hole.

In view of the provision of the resilient washers in the assembly of the heat-dissipating device and the circuit board of this invention, the heat-dissipating device can be secured stably on the circuit board. In addition, when the heat-dissipating device is subjected to an external force during impact, because the resilient washers abut against the circuit board, a portion of the external force could be absorbed or distributed to the circuit board. As a result, not only can the upper surface of the circuit board be prevented from damage, the likelihood of damage to the heat-generating component due to the external force can be reduced as well.

### BRIEF DESCRIPTION OF THE DRAWINGS

Other features and advantages of the present invention will become apparent in the following detailed description of the preferred embodiment with reference to the accompanying drawings, of which:

FIG. 1 is a schematic partly sectional view of a conventional assembly of a heat-dissipating device and a circuit board;

FIG. 2 is a schematic partly sectional view of another conventional assembly of a heat-dissipating device and a circuit board;

FIG. 3 is an exploded perspective view of the preferred embodiment of an assembly of a heat-dissipating device and a circuit board according to the present invention;

FIG. 4 is an exploded perspective view of a heat-dissipating device of the preferred embodiment;

FIG. 5 is a schematic partly sectional view of the heat-dissipating device of the preferred embodiment;

FIG. 6 is a schematic side view of the assembly of the preferred embodiment; and

FIG. 7 is a schematic partly sectional view of the assembly of the preferred embodiment.

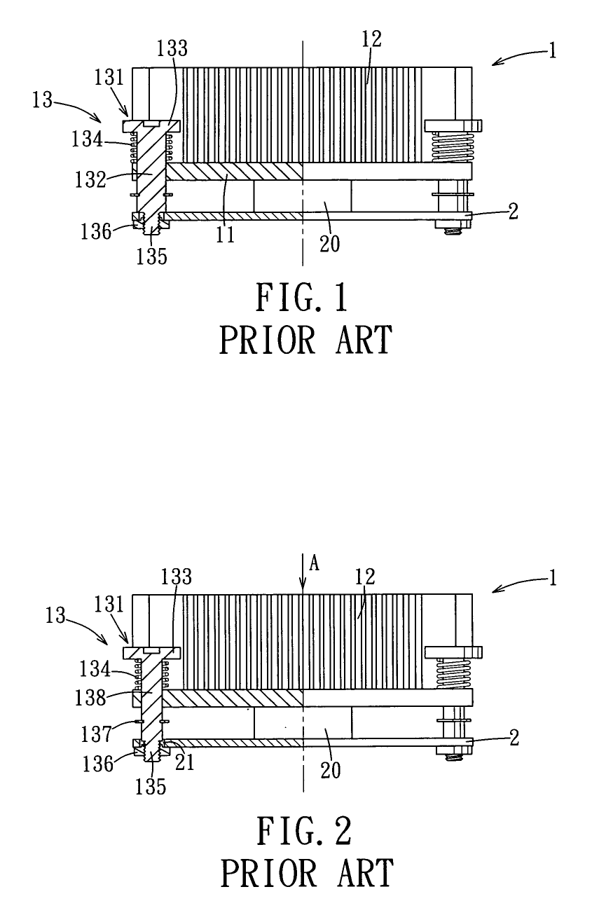

### DETAILED DESCRIPTION OF THE PREFERRED EMBODIMENT

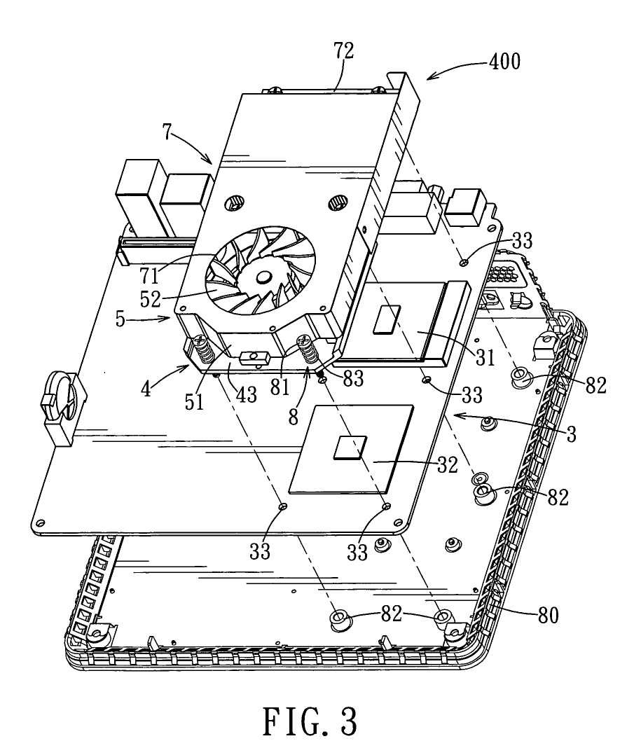

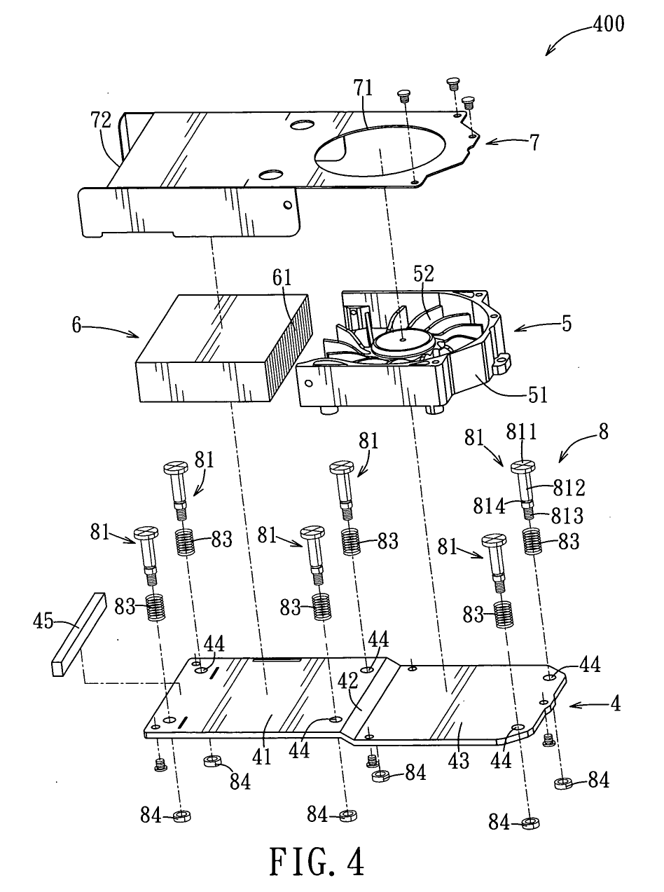

Referring to FIGS. 3 and 4, the preferred embodiment of an assembly according to the present invention is shown to comprise a circuit board 3 and a heat-dissipating device 400.

The circuit board 3 has two heat-generating components 31, 32 mounted on an upper surface thereof, and is formed with three pairs of spaced apart board holes 33. In this embodiment, the heat-generating component 31 disposed proximate to the rear side of the circuit board 3 is a central processing unit (CPU), whereas the heat-generating component 32 disposed proximate to the front side of the circuit board 3 is a north bridge chipset. The circuit board 3 is mounted on a housing 80.

The heat-dissipating device 400 includes a base plate 4 made of copper and elongated in shape, a heat-dissipating fan 5 mounted on a front side of the base plate 4, a heat-dissipating component 6 mounted on a rear side of the base plate 4, a cover body 7 for covering the heat-dissipating fan 5 and the heat-dissipating component 6, and a fixing device 8.

The base plate 4 includes a first plate body 41 disposed at the rear side and corresponding in position to the heat-generating component 31, a connecting portion 42 inclining downwardly and extending forwardly from a front side of the first plate body 41, and a second plate body 43 extending forwardly from a front side of the connecting portion 42 and corresponding in position to the heat-generating component 32. The base plate 4 further has three pairs of through-holes 44 formed in the first and second plate bodies 41, 43, each of the through-holes 44 being aligned with a respective one of the board holes 33. One pair of the through-holes 44 is formed proximate to the rear end of the first plate body 41, another pair of the through holes 44 is formed proximate to the front end of the second plate body 43, and the remaining pair of the through-holes 44 is formed in the first plate body 41 adjacent to the connecting portion 42. Moreover, the heat-dissipating device 400 further includes a sound-absorbing member 45 made of a soft material and mounted proximate to the rear end of the first plate body 41.

The heat-dissipating fan 5 includes a fan housing 51 corresponding in position to the second plate body 43 of the base plate 4, and a blade set 52 mounted in the fan housing 51. The fan housing 51 is generally U-shaped, and is open at top and rear sides thereof.

The heat-dissipating component 6 includes a plurality of spaced apart upright heat-dissipating fins 61 that extend in a front-to-rear direction.

The cover body 7 is formed with an air intake hole 71 that corresponds in position to the blade set 52, and has a rear side that is formed with an air vent hole 72 corresponding to the rear end of the heat-dissipating component 6.

The fixing device 8 includes three pairs of fastening members 81 that correspond respectively in position to the through-holes 44 in the base plate 4, three pairs of engaging members 82 that are mounted on the housing 80 and that correspond respectively to bottom sides of the board holes 33 in the circuit board 3, three pairs of biasing members 83 that are sleeved respectively on the fastening members 81, and three pairs of resilient washers 84 that are sleeved respectively on the fastening members 81. Each of the fastening members 81 is a screw, and has a head part 811, a shank part 812 that extends downwardly from a bottom face of the head part 811 and that has an outer diameter smaller than that of the head part 811, and a threaded connection part 813 that extends downwardly from a bottom face of the shank part 812 and that is capable of threaded engagement with a respective one of the engaging members 82. The shank part 812 has an outer surface formed with an engaging groove 814 that is disposed adjacent to the threaded connection part 813 for engaging the respective resilient washer 84. Each of the engaging members 82 is a nut. Each of the biasing members 83 is a compression spring. Each of the resilient washers 84 is made of a dielectric rubber material.

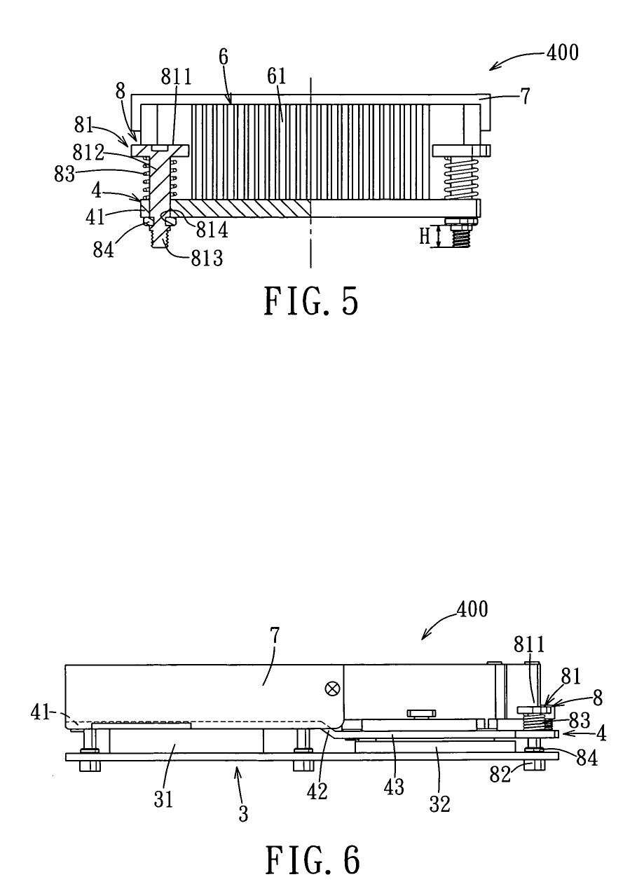

As shown in FIGS. 3, 4 and 5, when assembling the heat-dissipating device 400, the fan housing 51 of the heat-dissipating fan 5 is first secured on the top surface of the second plate body 43 of the base plate 4, and the heat-dissipating component 6 is mounted on the top surface of the first plate body 41 of the base plate 4 to correspond with the rear open side of the fan housing 51 of the heat-dissipating fan 5. Next, the cover body 7 is disposed to cover the heat-dissipating fan 5 and the heat-dissipating component 6 such that the air intake hole 71 of the cover body 7 corresponds in position to the blade set 52 of the heat-dissipating fan 5 and such that the air vent hole 72 of the cover body 7 corresponds to the rear end of the heat-dissipating component 6. The sound-absorbing member 45 is fixed adhesively proximate to the rear end edge of the first plate body 41 such that, aside from absorbing noise generated by the heat-generating air flow generated by the blade set 52 and flowing out of the air vent hole 72 after passing through the heat-dissipating component 6, the sound-absorbing member 45 can also guide the flow direction of the heat-dissipating air flow that flows through the air vent hole 72.

Next, each of the biasing members 83 is sleeved on the shank part 812 of the respective fastening member 81. The shank parts 812 are then extended through the through-holes 44 in the base plate 4 such that the opposite ends of the biasing members 83 abut respectively against the top surface of the base plate 4 and the bottom face of the head part 811 of the respective fastening member 81. A downward force is exerted on the head part 811 of each fastening member 81 such that the engaging groove 814 of the shank part 812 is exposed from the bottom surface of the base plate 4. A corresponding one of the resilient washers 84 is then sleeved on the shank part 812 of each fastening member 81 and engages the engaging groove 814. In this manner, the bottom face of each resilient washer 84 and the bottom end of each threaded connection part 813 cooperate to define a fastening depth (H). Due to the biasing action of the biasing members 83, the top faces of the resilient washers 84 abut closely against the bottom surface of the base plate 4, thereby fixing the fastening members 81 on the base plate 4 of the heat-dissipating device 400.

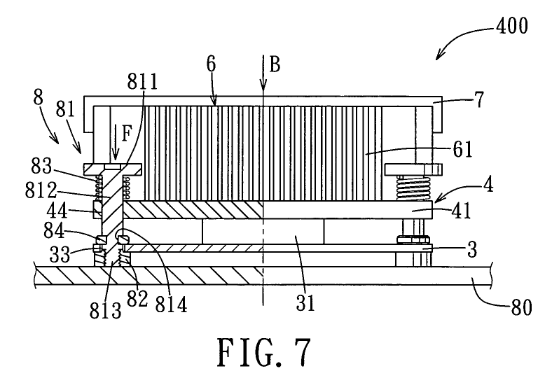

As shown in FIGS. 6 and 7, to assemble the heat-dissipating device 400 on top of the circuit board 3, the bottom surface of the first plate body 41 of the base plate 4 is disposed to abut against the top surface of the heat-generating component 31 on the circuit board 3, the bottom surface of the second plate body 43 is disposed to abut against the top surface of the heat-generating component 32 on the circuit board 3, and each of the fastening members 81 is registered with a respective one of the board holes 33 in the circuit board 3. Next, a downward force (F) is applied on the head part 811 of each fastening member 81, and the head part 811 of each fastening member 81 is rotated so as to cause the threaded connection part 813 of each fastening member 81 to extend through one of the board holes 33 and engage threadedly one of the engaging members 82 at the lower surface of the circuit board 3. When the fastening members 81 pass through the board holes 33 and are displaced downwardly by the fastening depth (H), the bottom faces of the resilient washers 84 abut against the upper surface of the circuit board 3, and further downward displacement of the fastening members 81 is no longer possible. The heat-dissipating device 400 is fixed on the circuit board 3 at this time.

On the other hand, to remove the heat-dissipating device 400 from the circuit board 3, the fastening members 81 are loosened until the threaded connection parts 813 are disengaged from the engaging members 82, thereby permitting separation of the heat-dissipating device 400 from the circuit board 3.

Since there is a height difference between the heat-generating components 31, 32 on the circuit board 3, therefore, through the design of the connecting portion 42 that forms a difference in horizontal levels between the first and second plate bodies 41, 43 of the base plate 4, the first and second plate bodies 41, 43 can complement the heat-generating components 31, 32 to effectively absorb heat generated by the heat-generating components 31, 32, thereby enhancing the heat-dissipating efficiency. Moreover, due to the design of the elongated shape of the base plate 4, and the arrangement of the three pairs of the fastening members 81 of the fixing device 8 at the front, middle and rear directions, the base plate 4 of the heat-dissipating device 400 is secured stably on the circuit board 3, and the arrangement of the middle pair of the fastening members 81 can prevent upward bending at the middle part of the base plate 4 when subjected to heat, thus ensuring that the first and second plate bodies 41, 43 can abut stably against the top surfaces of the heat-generating components 31, 32.

On the other hand, through the provision of the resilient washers 84, the fastening depth (H) of the fastening members 81 can be controlled so that when the heat-dissipating device 400 is assembled to the circuit board 3, the circuit board 3 is fixed stably between the engaging members 82 and the resilient washers 84. Since the resilient washers 84 are resilient, the upper surface of the circuit board 3 is not damaged when the resilient washers 84 abut therewith. Moreover, when the heat-dissipating device 400 is subjected to an external force (B) during impact, because the resilient washers 84 abut against the circuit board 3, a portion of the external force (B) can be absorbed or distributed to the circuit board 3, thereby reducing the likelihood of damage to the heat-dissipating components 31, 32 due to the external force.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. An assembly of a heat-dissipating device and a circuit board, said assembly comprising:
a circuit board having a heat-generating component mounted on an upper surface thereof, and formed with a plurality of spaced apart board holes; and
a heat-dissipating device including
a base plate disposed to abut against a top surface of said heat-generating component on said circuit board, and formed with a plurality of through-holes, each of which is aligned with a respective one of said board holes,
a heat-dissipating component mounted on top of said base plate and disposed above said heat-generating component,
a plurality of fastening members, each of which includes a shank part extending through one of said through-holes in said base plate and one of said board holes in said circuit board, a head part connected to a top end of said shank part and having an outer diameter larger than that of said shank part, and a threaded connection part extending downwardly from said shank part,
a plurality of biasing members, each of which has opposite ends that abut respectively against said base plate and a bottom face of said head part of a corresponding one of said fastening members,
a plurality of engaging members, each of which is disposed at a lower surface of said circuit board and engages said threaded connection part of a respective one of said fastening members, and
a plurality of resilient washers, each of which is sleeved on said shank part of a respective one of said fastening members, and abuts against said upper surface of said circuit board.

2. The assembly of claim 1, wherein each of said resilient washers is made of a dielectric rubber material.

3. The assembly of claim 1, wherein said shank part of each of said fastening members has an outer surface formed with an engaging groove that is disposed adjacent to said threaded connection part for engaging the respective one of said resilient washers.

4. The assembly of claim 1, wherein said heat-dissipating component includes a plurality of spaced apart upright heat-dissipating fins.

5. The assembly of claim 1, wherein said heat-dissipating device further includes a heat-dissipating fan mounted on top of said base plate for generating heat-dissipating air flow toward said heat-dissipating component.

6. The assembly of claim 5, wherein said base plate includes a first plate body mounted with said heat-dissipating component, a second plate body mounted with said heat-dissipating fan and disposed at a horizontal level lower than that of said first plate body, and a connecting portion interconnecting said first and second plate bodies.

7. The assembly of claim 6, wherein at least one of said through-holes is formed in said first plate body adjacent to said connecting portion.

8. The assembly of claim 7, wherein said heat-dissipating device further includes a cover body mounted on top of said base plate and disposed to cover said heat-dissipating component and said heat-dissipating fan, said cover body having a top side formed with an air intake hole for establishing fluid communication between said heat-dissipating fan and the outside environment, and a rear side formed with an air vent hole for establishing fluid communication between said heat-dissipating component and the outside environment.

9. The assembly of claim 8, wherein said heat-dissipating device further includes a sound-absorbing member mounted on a top side of said first plate body and disposed adjacent to said air vent hole.
